(19) United States
(12) Patent Application Publication
(10) Pub. No.: US 2006/0214089 A1
(43) Pub. Date: Sep. 28, 2006

(54) Method and apparatus for real time output monitoring of light sources and flexible sensitivity adjustment of light sensors

(76) Inventor: Byoung E. An, Saratoga, CA (US)

Correspondence Address: Byoung E. An, 13078 Via Escuela Ct., Saratoga, CA, 95070, US

(21) Appl. No.: 11/087,915

(22) Filed: Mar. 22, 2005

(51) Int. Cl. H01L 31/00

(52) U.S. Cl. 250/214.1

(57) ABSTRACT

A noble method and apparatus was invented to provide a simple and flexible way to monitor the output signal of various light sources and to adjust the sensitivity of light sensors in real time. A preferred embodiment of the current invention consists of a tri-color light sensor with integral optical filters, a sensor mounting mechanism, a signal amplification circuit with an operational amplifier and a gain control logic for each channel, and a signal conditioning circuit. A noble connector pad configuration allows a secure and compact light sensor module.

### CROSS-REFERENCE TO RELATED APPLICATIONS

Not Applicable

### FEDERALLY SPONSORED RESEARCH

Not Applicable

### Sequence Listing or Program

Not Applicable

### BACKGROUND OF THE INVENTION—FIELD OF INVENTION

The invention relates to a method and apparatus for real time output monitoring of light sources and flexible sensitivity adjustment of light sensors in a printed circuit board.

### BACKGROUND OF THE INVENTION

Light sources are used in electronic circuits to facilitate visual testing of design and manufacturing quality of electronic circuits and printed circuit boards (PCBs). Light sources are also used to monitor the quality of electronic signals in those circuits during operation of PCBs. Other uses of light sources include displaying visual images and textual data on computer monitors and display screens. Typical light sources include electric lamp, light emitting diode (LED), LCD, PDP and CRT.

Previously, LED displays typically used LEDs with color-coated lenses or lenses with color filters to display a particular color (wavelength). Usually LEDs with three primary colors (red, green and blue) with various light intensity are used to display various colors. When LEDs with colored lenses are used, it is easy to visually inspect the color level of each LED. However, the light intensity from each LED is reduced when the LED light is transmitted through the colored lens.

Recently developed colored LEDs with transparent lenses produce higher intensity light with a reduced power consumption because they do not need color filters. However, it makes visual inspection and monitoring of the color (wavelength) and light intensity of colored LEDs very difficult. Therefore, semiconductor light sensors are typically used to measure and verify the light wavelength and intensity of light sources.

Signal from semiconductor light sensors are of very low level current, sometimes in the microamperes or below level. Light sensor output signal levels can vary widely depending upon the type of light sources and light intensity.

A current limit resistor circuit is typically used in parallel between the light sensor input terminal and the ground to limit and control the output current from the light sensor. The resistance of the current limit resistor is chosen by the average level of the light intensity at a design light frequency of the light source. However, if the light source signal level is significantly lower or higher than the design value, the current limit resistor needs to be changed manually. Often the resistance value of the current limit resistor has to be determined by trial and error for each application of the signal sensing device. In LED light signal monitoring applications for PCBs, the signal sensing device size is limited for PCBs where LEDs are typically arranged in a compact manner to minimize the PCB size. As the size of the signal sensing device becomes smaller, it is more difficult and time consuming to change or replace components such as current limit resistors in the signal sensing device.

Schmitt (U.S. Pat. No. 6,490,037) uses an output voltage from the sensor corresponding to the intensity of the light source. Typically a bias resistor is used adjacent to the light sensor to provide an output voltage from the sensor. The sensor assembly with the bias resistor is bulky. It is also cumbersome to change or replace the bias resistor when the current from the light sensor is significantly different from the design value due to change in the light intensity measurement application parameters.

The current invention can eliminate the manual change or rework of the sensing circuit design which has traditionally been customized for each application. In the current invention, the signal from the light sensor can be monitored and its sensitivity can be adjusted in real time in a flexible manner with a simple variable amplification circuit without manual component replacement. This invention minimizes and oftentimes eliminates the tight control requirement of the light source—sensor distance in a PCB test system.

### SUMMARY

A noble method and apparatus was invented to provide a simple and flexible way to monitor the output signal of various light sources and to adjust the sensitivity of light sensors in real time. A preferred embodiment of the current invention consists of a tri-color light sensor with integral optical filters, a sensor mounting mechanism, a signal amplification circuit with an operational amplifier and a gain control logic for each channel, and a signal conditioning circuit. A noble connector pad configuration allows a secure and compact light sensor module.

### BRIEF DESCRIPTION OF THE DRAWINGS

FIG. 1 is a schematic diagram of a light sensor module and a light sensor signal conditioning logic module according to a preferred embodiment of this invention.

FIG. 2 is a schematic view of a tri-color light sensor.

FIG. 3 is an exploded view of a spring-loaded compliant connector for a light sensor lead.

FIG. 4 is a schematic representation of a side-mounted sensor module according to a preferred embodiment of this invention.

FIG. 5 is a schematic representation of a connector pad configuration for a side-mounted sensor assembly according to a preferred embodiment of this invention.

FIG. 6 is a schematic representation of a connector pad configuration for a side-mounted sensor assembly according to a preferred embodiment of this invention.

FIG. 7 is a schematic representation of a dual connector pad configuration for a side-mounted sensor assembly according to a preferred embodiment of this invention.

### DESCRIPTION OF THE PREFERRED EMBODIMENTS

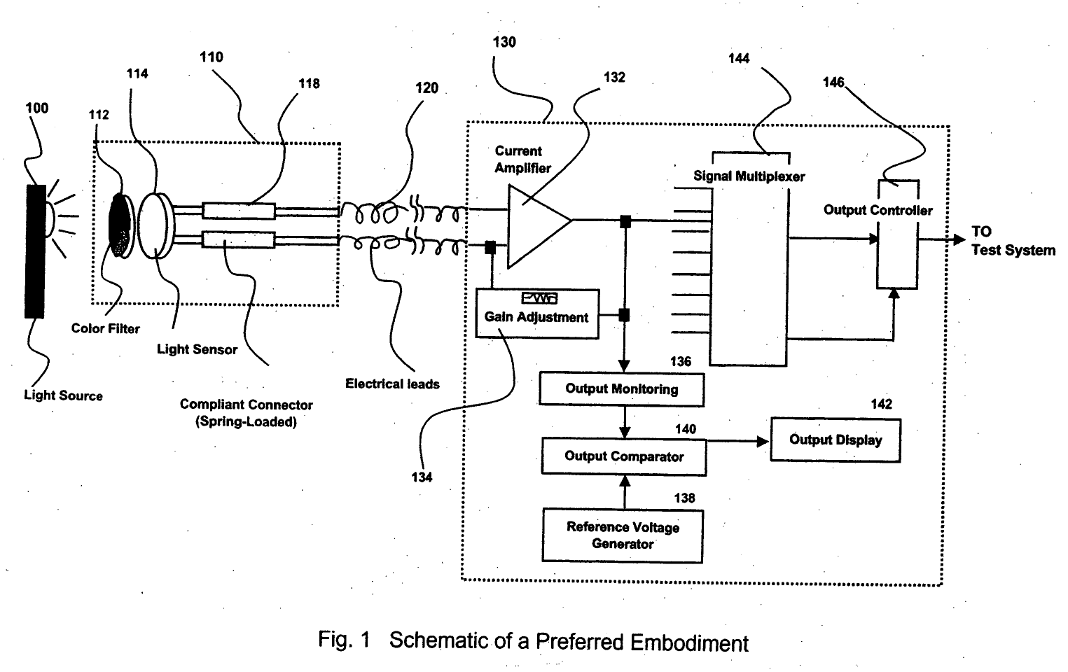

FIG. 1 shows a schematic diagram of a light sensor module and a light sensor signal conditioning logic module according to a preferred embodiment of this invention.

In a light sensor assembly 110, the light sensor 114, typically a photosensitive semiconductor, detects the light intensity of a certain frequency (determined by the color of the color filter 112) from the light source 100, typically a light emitting diode (LED). Spring-loaded compliant connectors 118 are used to prevent the light sensor assembly 110 from damage when the light sensor assembly 110 accidentally hits the light source 100 or the device, typically a printed circuit board, on which the light source 100 is mounted. FIG. 3 is an exploded view of a spring-loaded compliant connector for a light sensor lead.

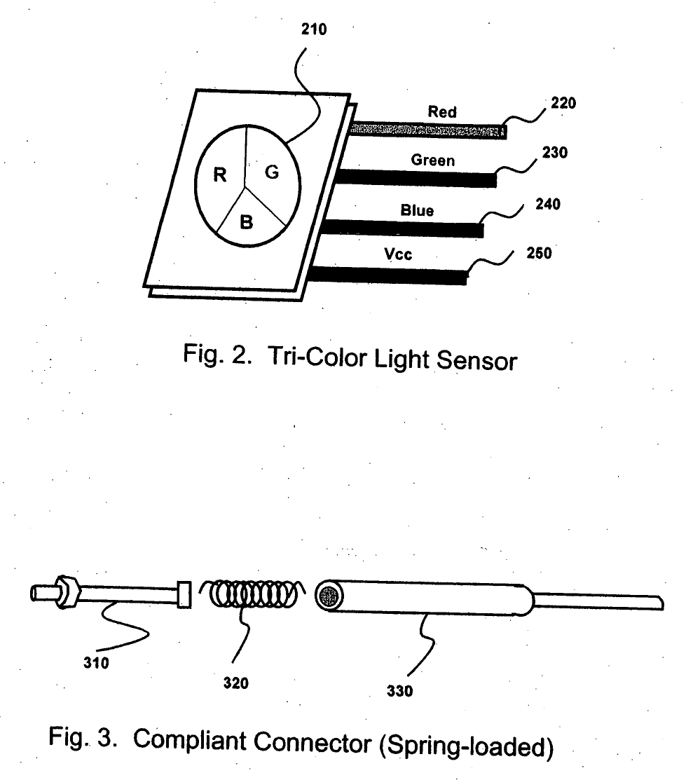

A preferred embodiment of this invention uses a single or multi-color photosensitive semiconductor as the light sensor. FIG. 2 shows a schematic of a tri-color photosensitive semiconductor 210 with four leads: R (red) 220, G (green) 230, B (blue) 240, and C (common) 250. A desired color can be measured by a combination of any one, two or three signal output leads. For example, R 220 and C 250 are used to measure the light intensity from a red LED, a combination of R 220, G 230 and C 250 can be used to measure the light intensity from a yellow or amber (orange) LED, and a combination of R 220, G 230, B 240 and C 250 can be used to measure the light intensity from a white LED.

A preferred embodiment of the invention uses a tri-color photosensitive semiconductor with four leads as the light sensor. If the light source is not a white color light source, not all the four electrical leads have to be connected. For example, only the common and the electrical lead for red color are needed to measure a red color LED. A change in a light source specification (such as color) can be accommodate easily with a simple rearrangement and/or reconnection of the electrical leads for the light sensor.

The output signal from the light sensor 114 is typically of a low level current. Instead of converting this current into a voltage typically with a bias resistor as done by Schmitt (U.S. Pat. No. 6,490,037), this invention feeds the current output directly to a signal conditioning logic module 130 through electrical leads 120. A bias resistor is not needed in this preferred embodiment of this invention. The signal conditioning logic module 130 is typically situated in a printed circuit board where typically multi-channel signals are conditioned and fed to a test system through a signal multiplexer 144.

Because of the low level current output from the semiconductor light sensor, a light noise elimination circuit is optionally used in the signal conditioning circuit design of the semiconductor light sensor. For this purpose, capacitors are typically used between the input terminal and the ground and/or between the output terminal and the ground.

An impedance matching resistor circuit is optionally used in series between the light sensor output terminal and the light signal amplification circuit input terminal to match the impedance between the circuits.

The low level current from the light sensor 114 is converted to a voltage signal in a current amplifier 132. The amplification ratio (gain) can be adjusted manually or electronically by a variable gain adjustment loop 134 over a wide range to accommodate the various level of the sensor output signal due to the variation of the light intensity of the sensor or the variation of the distance between the light source 100 and the sensor module 110. Because of this variable gain control 134, the distance between the light source 110 and the sensor module 110 does not have to be maintained tightly. However, if a sensor module uses a fixed gain amplifier or a bias resistor as used by Schmitt (U.S. Pat. No. 6,490,037), this distance has to be maintained typically to less than 0.15 inch. On the other hand, in a preferred embodiment of this invention, the sensor—source distance variance can be accommodated by the variable gain control mechanism 134 to 0.50 inch or more. This flexibility in the distance between the light source and the light sensor minimizes or oftentimes eliminates the costly and time consuming manual rework of the sensor assembly and/or sensor positioning in the light monitoring system. The sensitivity of the sensor can be adjusted easily with a variable gain adjustment loop134, typically a potentiometer, without mechanical rework or modification after the light monitoring fixture is installed in the system.

In a preferred embodiment of this invention, the output voltage signal from the current amplifier 132 is monitored by an output monitoring logic consisting of 136, 138, 140 and 142. A reference voltage generator generates a voltage corresponding to a pass/fail threshold level of the light source which can be set by the factory or by the user. An output comparator 140 compares the reference voltage 138 and the amplified output signal 136, and generates a pass/fail signal. In a preferred embodiment of this invention, this pass/fail signal is used to turn on or off an LED to display the pass/fail status of the light source 100 operation visually. This embodiment of the invention allows a visual verification and/or determination of the status and functionality of the light source(s), preferably LED(s), with just a simple output display, preferably with LEDs, even without a test system. The pass/fail signal for the output display and optionally for the test system can be set with a known good sample without a system calibration. With a test system, the pass/fail status of the light sources can be monitored and the test data can be processed further.

In a preferred embodiment of this invention, a signal multiplexer is used to process output signals from a plurality of light sensors 112 for a plurality of light sources 100 according to a pre-defined data processing and transport logic. This data from the multiplexer 144 can be conveyed to a PCB test system to test the operation of the light sources, preferably LEDs, on the PCB.

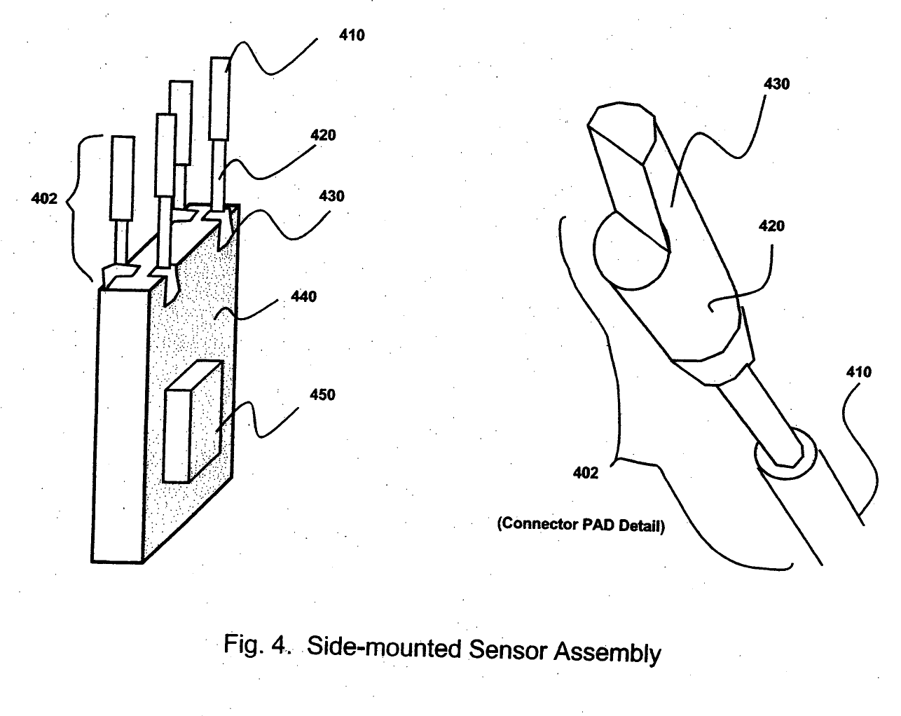

FIG. 4 shows a preferred embodiment of a light sensor module of this invention. A side-mounted light sensor module is typically used to measure and monitor a light source, typically an LED, mounted horizontally with the light source's optical axis parallel to the PCB surface. A light sensor 450, preferably a tri-color photosensitive semiconductor, is mounted on a mounting plate 440, preferably a small but thick printed circuit board. Specially configured connector pads 430 are used to connect electrical connectors 402 to electrical leads from the light sensor 450. In a preferred embodiment of the invention, spring-loaded electrical probes as shown in FIG. 3 are used as connectors 402.

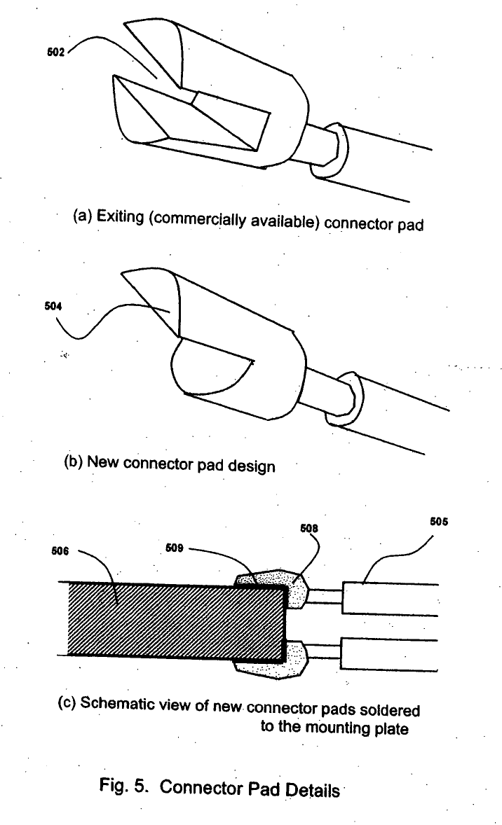

FIG. 5 shows a detailed view of the connector pad configuration. Commercially available electrical probes typically use a pad configuration with a slotted end 502 to connect them to a printed circuit board with soldering. A preferred embodiment of this invention uses a connector pad configuration as shown in FIG. 5 (b) which has a cut-out, equivalent to a FIG. 5 (a) configuration with one side part removed. FIG. 5 (b) configuration allows the connector 505 (electrical probe) to be attached, preferably with soldering 509, to a mounting plate 506, preferably a printed circuit board. A multi-color light sensor has multiple electrical leads. For example, a tri-color photosensitive semiconductor has four electrical leads, typically common, red, green and blue, as shown in FIG. 2. The new connector pad configuration as shown in FIG. 5 (b) facilitates the electrical connectors to be attached, preferably soldered, to the mounting plate, preferably a printed circuit board, securely because of the large contact area 509 between the pad 508 and the mounting plate 506. Another benefit of this new pad configuration is the reduced size of the mounting pad 440, 506 because of the compact arrangement made possible with the new pad configuration as shown in FIG. 4 and FIG. 5 (c).

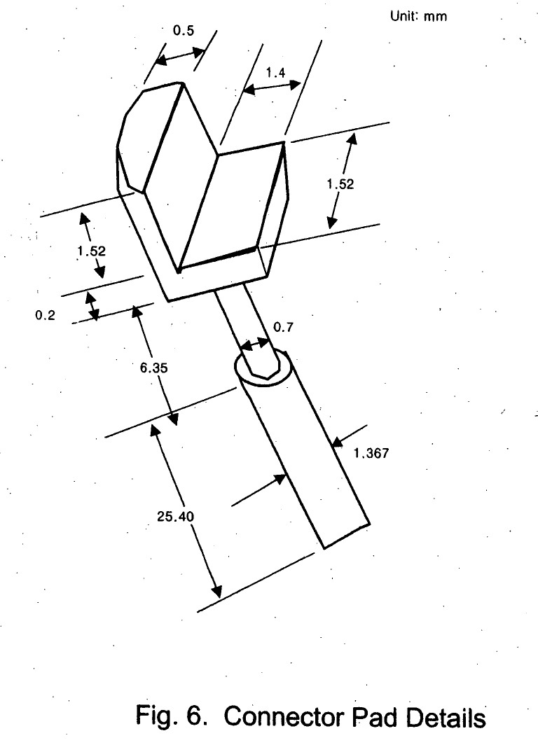

FIG. 6 is a schematic representation of a connector pad configuration for a side-mounted sensor module according to a preferred embodiment of this invention. Typical dimensions (in millimeters) of a preferred embodiment of the invention are indicated in FIG. 6 for reference purpose only. Dimensions can be varied as needed for connector pads of similar configurations.

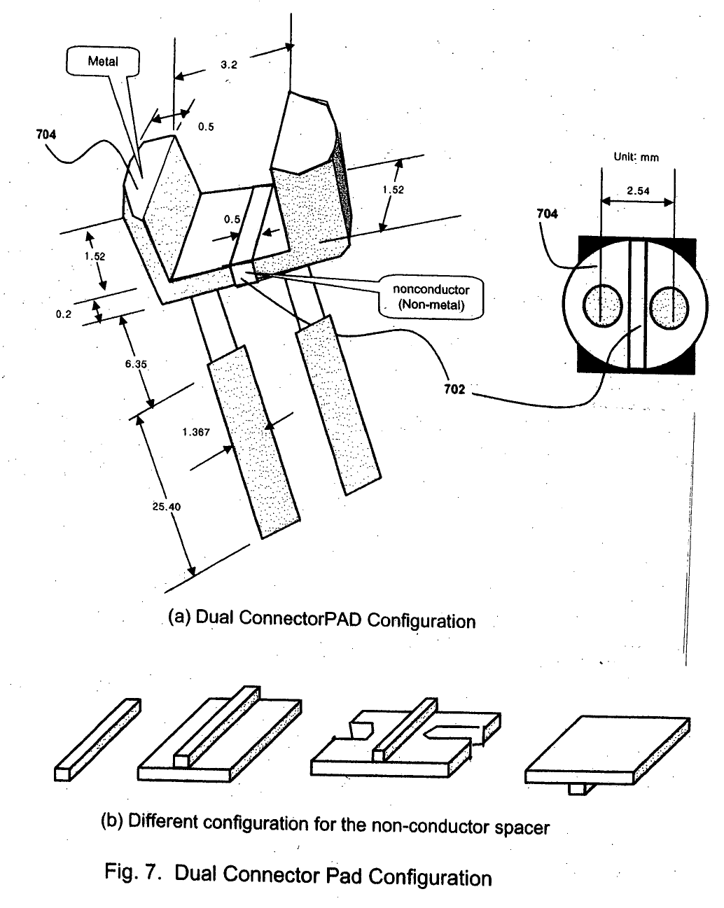

FIG. 7 is a schematic representation of a dual connector pad configuration for a sensor module according to a preferred embodiment of this invention. Two connector pads are glued or tied together with an electrically insulating spacer 702. The spacer 702 can be of any configuration as long as it ties the two connector pads 704 together mechanically, preferably by brazing, gluing or soldering. Several acceptable spacer configurations are shown in FIG. 7 (b) for reference purposes only. Typical dimensions (in millimeters) of a preferred embodiment of the invention are indicated in FIG. 7 for reference purposes only. Dimensions can be varied as needed for connector pads of similar configurations.

The foregoing detailed description of the invention has been presented for purposes of illustration and description. It is not intended to be exhaustive or to limit the invention to the precise form disclosed. Many modifications and variations are possible in light of the above descriptions. The described embodiments were chosen in order to best explain the principles of the invention and its practical application to thereby enable others skilled in the art to best utilize the invention in various embodiments and with various modifications as are suited to the particular use contemplated.

What is claimed is:

1. A noble apparatus for monitoring an output signal of a light source, the apparatus comprising:
a light source; a sensor module having a multi-color light sensor mounted on a sensor mounting pad and positioned adjacent to the light source, the sensor having at least red, green and blue light sensing elements providing output currents from the said red, green and blue light sensing elements corresponding to the intensity and wavelength of the light from the said light source; a sensor mounting pad with spring-loaded compliant leads; and a signal conditioning module located remotely from the sensor module where the current signal from at least one color sensing element in the said light sensor is amplified and converted to a voltage in an operational amplifier, the amplifier having a variable gain control logic, and the amplified and converted signal being used to generate a pass/fail signal corresponding to the operation of the light source.

2. The apparatus of claim 1 wherein the light source is a light-emitting diode (LED).

3. The apparatus of claim 1 wherein the light sensor is a semiconductor photodiode.

4. A method for monitoring an output signal of a light source, the method comprising: mounting a multi-color light sensor on a sensor mounting pad with spring-loaded compliant leads; positioning the light sensor mounted on a sensor mounting pad adjacent to a light source; sending the current signal from at least one color sensing element of the multi-color light sensor to a signal conditioning module; amplifying and converting the signal from the light sensor into a voltage in an operational amplifier where a variable gain control logic circuit is used to adjust the output voltage level in real time; and generating a pass/fail monitoring signal corresponding to the operation of the light source.

5. The method of claim 4 wherein the light source is a light-emitting diode (LED).

6. The method of claim 4 wherein the light sensor is a semiconductor photodiode.

7. An apparatus for mounting connecting leads on a light sensor mounting pad, the apparatus comprising: a pad with at least two electrically conducting mounting surfaces which are connected with each other electrically and positioned at an angle between 60 and 120 degrees with each other; and at least one connector lead soldered, brazed or otherwise attached to the said pad, the connector lead having at least two mounting surfaces at the same angle as the angle between the mounting surfaces of the said pad, the connector lead having a spring-loaded compliant mechanism to accommodate an axial mechanical load in the said connector lead.

8. A method of mounting connecting leads on a light sensor mounting pad, the method comprising: soldering, brazing or otherwise attaching at least one connector lead to a light sensor mounting pad, the sensor mounting pad having at least two electrically conducting mounting surfaces which are connected with each other electrically and positioned at an angle between 60 and 120 degrees with each other, and the connector lead having at least two mounting surfaces at the same angle as the angle between the mounting surfaces of the said pad, the connector lead having a spring-loaded compliant mechanism to accommodate an axial mechanical load in the said connector lead.
